(19) United States
(12) Patent Application Publication
(10) Pub. No.: US 2007/0218597 A1
(43) Pub. Date: Sep. 20, 2007

(54) Structure and method for controlling the behavior of dislocations in strained semiconductor layers

(75) Inventors: Stephen W. Bedell, Wappingers Falls, NY (US); Joel P. DeSouza, Putnam Valley, NY (US); Devendra K. Sadana, Pleasantville, NY (US); Klaus W. Schwarz, Somers, NY (US); Alexander Reznicek, Mount Kisco, NY (US)

Correspondence Address: Robert M. Trepp;IBM CORPORATION, Intellectual Property Law Dept., P.O. Box 218, Yorktown Heights, NY, 10598, US

(73) Assignee: International Business Machines Corporation, Armonk, NY (US)

(21) Appl. No.: 11/384,718

(22) Filed: Mar. 15, 2006

(51) Int. Cl. H01L 21/8232; H01L 21/335

(52) U.S. Cl. 438/142

(57) ABSTRACT

A structure and method for controlling the behavior of dislocations in strained semiconductor layers is described incorporating a graded alloy region to provide a strain gradient to change the slope or curvature of a dislocation propagating upwards or gliding in the semiconductor layer in the proximity of the source and drain of a MOSFET. The upper surface of the strained semiconductor layer may be roughened and/or contain a dielectric layer or silicide which may be patterned to trap the upper end of dislocations in selected surface areas. The invention solves the problem of dislocation segments passing through both the source and drain of a MOSFET creating leakage currents or shorts therebetween.

### FIELD OF THE INVENTION

This invention relates to strained semiconductor layers for forming integrated circuit chips and more particularly to controlling the behavior of dislocations in strained semiconductor layers.

### BACKGROUND OF THE INVENTION

Forming metal oxide semiconductor field-effect transistors (MOSFETs) on Si layers under tensile strain allows for the continued development of high-performance/low-power CMOS integrated circuits. The enhanced charge carrier mobility in strained Si compared to unstrained Si allows for the increase of on-state transistor current without the need to decrease the physical dimensions of the device; which is becoming increasingly more difficult to do. For strained Si applications, the two main approaches used to create strain in the transistor channel region are 1) growing a thin Si layer on a relaxed SiGe alloy layer (global strain) and 2) straining the channel region using integrated circuit (IC) process-level techniques such as refilling the source and drain (S/D) regions on either side of the channel with compressively strained SiGe, or depositing strained dielectric layers (such as silicon nitride) on or near the transistor to impart lattice strain to the channel (local strain). The main problem with local strain techniques is that as the device pitch (spacing between devices) decreases, the extent and integrability of such approaches becomes quite challenging; there is very little S/D region left to use. The main challenge to global strain Si has been the device failures associated with crystal defects. Low-defect compositionally-graded SiGe layers have been demonstrated to have 10⁵ dislocations/cm² as well as low-defect silicon germanium on insulator (SGOI), however, after growing the strained Si layer on the SiGe alloy, the dislocations can glide in the strained Si layer and leave behind a misfit dislocation segment along the Si/SiGe interface. Because the thickness of the strained Si layer is typically less than 200 A, these interfacial dislocation segments are able to intersect the source and drain doped regions, and thus provide a current leakage path between the source and drain. If the Si layer is very thin (<˜50 A ), then it is possible to inhibit the formation of the interfacial dislocation segment. Such very thin layers are prohibitively thin for current CMOS fabrication. However, because of the enhanced dopant diffusion of As or P in SiGe, the S/D formation is less controlled after ion implantation and S/D activation annealing. What is needed is a way to lessen the impact of any unintentional interfacial dislocation segment generation during device fabrication while at the same time keeping the SiGe layer further below the S/D areas to limit enhanced dopant diffusion.

### SUMMARY OF THE INVENTION

A structure and method for controlling the behavior of dislocations is described comprising:

a substrate of relaxed single crystal semiconductor material,

a strained epitaxial semiconductor layer formed over the substrate having a first region of an alloy of varying composition with height to provide a strain gradient up to a predetermined height therein,

the strained epitaxial seminconductor layer having a second region under strain of constant composition above said predetermined height, and

a semiconductor device formed in said second region above said first region.

The invention described herein pertains to a particular strain-graded topmost layer, grown on the SiGe buffer layer, which provides 1) a Si surface for the transistor channel region and 2) a strain vs. depth profile that makes the region where interfacial dislocation segments are created far enough below the surface to be beneath the S/D regions thereby reducing the probability of shorting the S/D regions of FETs. An additional benefit of creating a strain-graded cap layer is that the Ge concentration can be made to be a smooth function of depth which limits Ge diffusion into the Si channel region and also reduces dopant diffusion.

Another embodiment of the present invention contemplates the deliberate micro-roughening of the upper surface of the strained semiconductor layer. This embodiment provides a method of pinning the motion of the dislocations by creating a barrier to dislocation glide. The deliberate micro-roughening can be performed everywhere on the exposed surface or in pre-specified non-critical regions of the surface to act as localized dislocation traps. The advantage of the roughened surface is that it can be used to increase the critical thickness of the strained layer at a given Ge concentration or gradient.
The strain graded top most layer may be patterned and may be a semiconductor material of Ge or of III-V elements such as GaAs and InP. The buffer layer and the top most layer may have a selected crystal orientation such as <100> and <110>. The substrate may be one of bulk semiconductor, silicon-on-insulator (SOI) or silicon germanium on insulator (SGOI). In addition to FET or MOSFET devices, the invention is applicable to controlling dislocations with respect to bipolar transistors, photo detectors and light emitting diodes (LEDs).

### BRIEF DESCRIPTION OF THE DRAWING

These and other features, objects, and advantages of the present invention will become apparent upon consideration of the following detailed description of the invention when read in conjunction with the drawing in which:

FIG. 1 is a cross section view of a CMOS device having a strained channel of the prior art.

FIG. 2 is a cross section view of a CMOS device having a strained channel of the prior art.

FIG. 3 is a cross section view of a CMOS device having a graded SiGe strained region below a Si channel.

FIG. 4 is a cross section view of a CMOS device having a SiGe graded strained region below a Si channel with a roughened upper surface and/or a dielectric or silicide layer above the Si upper surface.

FIG. 5 is a cross section view of a CMOS device having a SiGe graded strained region below a Si channel with a roughened upper surface and/or a dielectric or suicide layer above the Si upper surface on SGOI.

### DESCRIPTION OF THE PREFERRED EMBODIMENTS

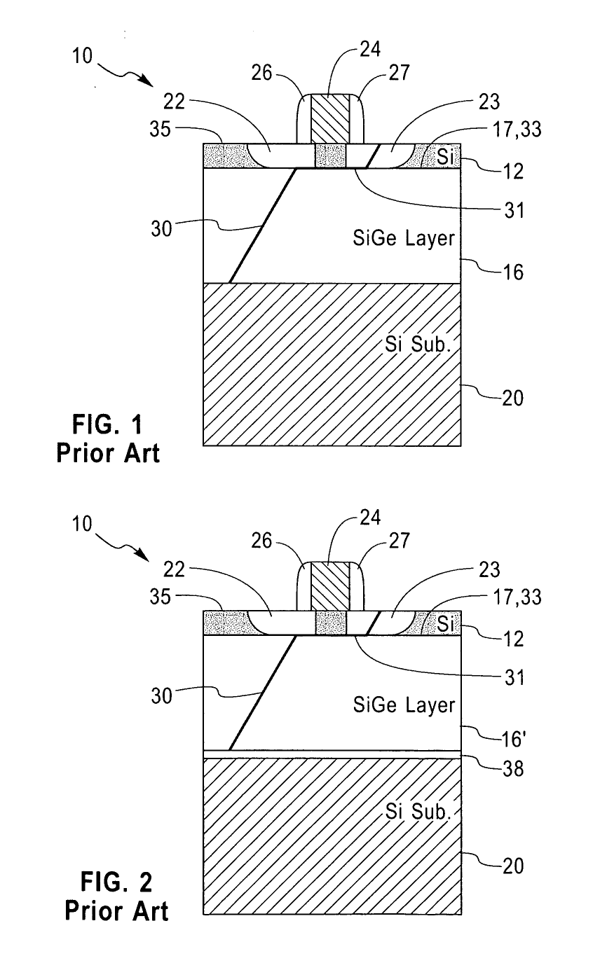

FIG. 1 shows a cross section view of a MOSFET 10 formed on a strained semiconductor layer 12 which may be Si or Si containing. Strained layer 12 is formed over a SiGe layer 16 which in turned is formed over a substrate 20. Strained layer 12 may be formed by epitaxial deposition over SiGe layer 16. SiGe layer 16 may be epitaxially deposited over substrate 20 which may be single crystalline. The amount of Ge in layer 16 may be increased with layer thickness and then relaxed to form a crystal lattice spacing greater than the future lower surface of layer 12 to cause global bidirectional strain in layer 12. Thus, layer 16 may be graded SiGe up to the upper surface 17 of layer 16. Layer 12 may be of constant Si or SiGe composition.

Alternatively in place of SiGe graded layer 16, layer 16 may be a Silicon Germanium on Insulator (SGOI) as shown in FIG. 2.

In FIGS. 1-5, MOSFET 10, has a source 22, drain 23 and gate 24. Sidewall spacers 26 and 27 are also present. Source 22 and drain 23 are formed by ion implantation for example. The depth of source 22 and drain 23 is determined by the depth of ion implantation and by the subsequent activation anneal. For an n type MOSFET, the doping impurity may be arsenic or phosphorus which diffuses more rapidly in SiGe. The more Ge in SiGe the more the diffusion. Thus, Si is preferred to be in the source and drain regions.

FIG. 1 shows a typical dislocation 30 in layer 16 which propagates upwards to source 22 and glides sideways along interface 33 as shown by dislocation segment 31 when it intersects interface 33 between layers 16 and 12. Dislocation 30 propagates upwards from interface 33 through drain 23 to the upper surface 35 of layer 12. The dislocation segment 31 is formed due to the abrupt strain at interface 33. As shown in FIG. 1, the dislocation provides a current path for shorting the source 22 and drain 23. Originally during growth of layer 12, dislocation 30 follows a path that is generally straight to upper surface 35 of layer 12. During growth of layer 12 or during subsequent processing, dislocation 30 glides along interface 33 to form segment 31.

Layer 12 is normally thin to keep layer 12 from relaxing.

In FIG. 1, the presence of interfacial misfit dislocation 30 can short out the source 22 and drain 23 of MOSFET 10.

FIG. 2 shows the same structure as FIG. 1 except layer 16′ is a relaxed SiGe layer of constant composition on an insulator 38 which in turn is over substrate 20 i.e. SGOI.

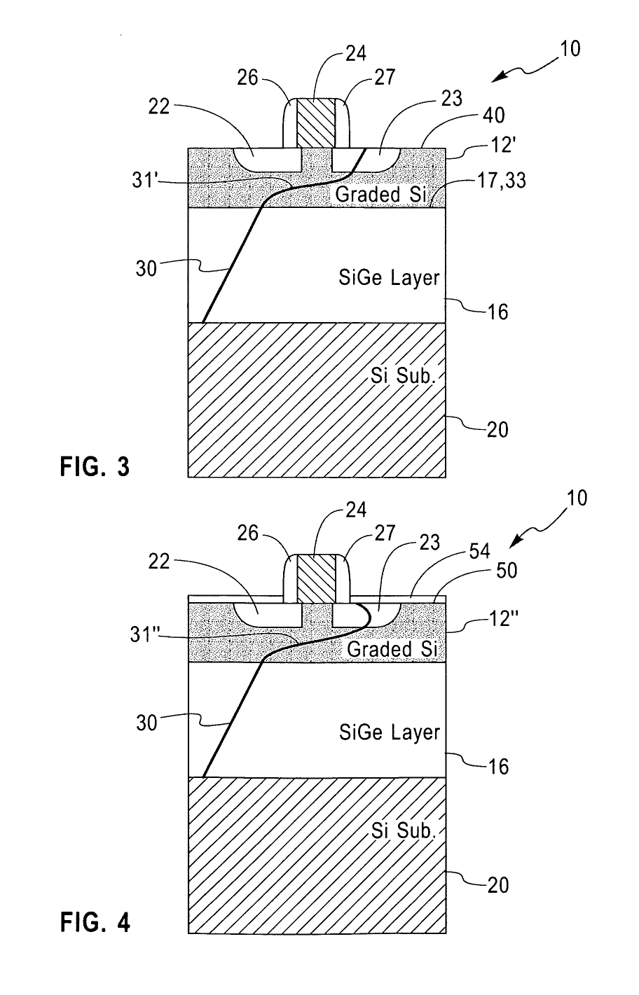

FIG. 3. is a cross section view of a preferred embodiment of the invention. In FIG. 3, the strain in layer 12′ is adjusted to vary from zero or near zero at interface 33 to a given strain in pure silicon at the upper surface 40. The strain is controlled by alloying Si with Ge at a fraction x. For example with a SiGe layer where x is 0.2, the in-plane lattice parameter for a fully relaxed layer is approximately 0.75 percent greater than that of Si. If Si is grown directly on interface 33, it will have a tensile strain of 0.75 percent. If however, the initial concentration of 12′ has an x of 0.2 and x is decreased linearly with height to upper surface 40 to an x value of 0, then the strain at the lower portion of 12′ near interface 33 is near zero and the strain near the upper surface 40 is 0.75 percent tensile strain. This strain gradient in layer 12′ changes the curvature of the dislocation propagating upwards or gliding in layer 12′ compared to an abrupt strain profile at interface 33 as shown in FIG. 1. By having the dislocation sloping or curving through layer 12′ with one side of the dislocation lower than the other, the dislocation is less likely to pass through both the source and drain of MOSFET 10.

The total strain energy of the graded Ge layer 12′ is the product of the strain squared times the thickness. In the graded layer, it is not a fixed strain so the total strain energy is the integral of the strain squared at a given point integrated over the thickness of the layer.

Since the composition in layer 12′ is graded, layer 12′ can be made thicker for the same total strain energy. By having layer 12′ thicker, the source and drain dopants are further away from interface 33 and the SiGe in layer 16. In a preferred embodiment, the total strain energy is such that layer 12′ is thermodyamically stable against dislocation production. By engineering the Ge profile (and thus the strain profile) through the layer 12′ the shape of the dislocation 31′ can be controlled in such a way as to reduce the probability of S/D shorting upon movement of the dislocation.

Another advantage of using a compositionally reversed-grade layer 12′ is that both Ge up-diffusion and arsenic and/or phosphorus down-diffusion is significantly reduced. It is noted that the Ge up-diffusion flux is directly proportional to the concentration gradient. Layer 12′ is thicker than layer 12 and already has a Ge gradient thereby reducing the flux of up-diffusion.

Layer 12′ may have a top thickness of pure or substantially pure Si for the device structure. For a MOSFET, it is preferred to have the channel comprise pure Si to avoid carrier scattering by Ge atoms.

Layer 12″ may be made thicker and yet maintain thermodynamic stability against dislocation formation by roughening the upper surface of layer 12″ sufficient to pin dislocations at the surface. Referring to FIG. 4, upper surface 50 of layer 12″ is roughened. The amount of roughness such as the root mean squared should be in the range from 2 nm to 20 nm. The roughness may be patterned in preselected areas such as above source 22 and drain 23 and above the periphery of the MOSFET 10 outside source 22 and drain 23 to serve as dislocation traps for the top of dislocation segment 31″.

Roughening of upper surface 50 may be achieved by dry-etching such as RIE, wet-etching such a KOH etching, epitaxial growth/etching or anodization techniques well known in the art.

In place of roughening upper surface 50 or in conjunction with a roughened upper surface 50, dislocations at the upper surface 50 may also be pinned by a dielectric layer 54 for example a compressively strained silicon nitride layer or silicide layer. By pinning the dislocations at the upper surface 50, the thickness of layer 12″ can be substantially increased for example two times the thickness of layer 12′ in FIG. 3 and four times the thickness of layer 12 in FIG. 1. The dielectric layer may also be patterned on upper surface 50.

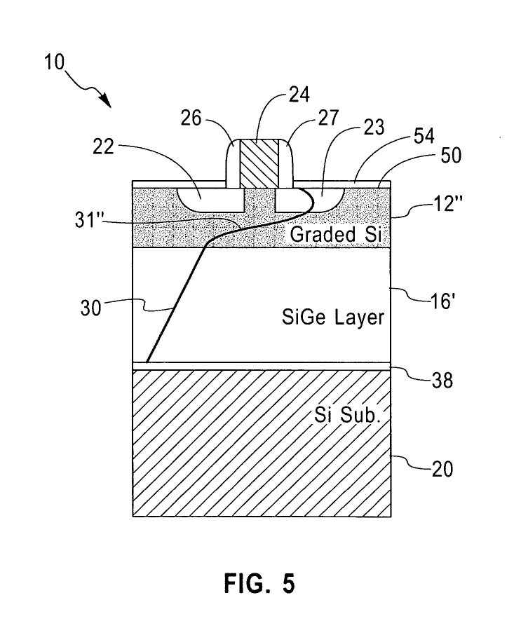

FIG. 5 shows an embodiment of the invention similar to FIG. 4 except SiGe layer 16′ is a relaxed SiGe layer of constant composition on an insulator 38 which in turn is over substrate 20 as shown in FIG. 2 to provide a SGOI structure.

In FIGS. 1-5 like references are used for functions corresponding to the apparatus of FIGS. 1-5.

While there has been described and illustrated a structure for controlling the behavior of dislocations in strained semiconductor layers, it will be apparent to those skilled in the art that modifications and variations are possible without deviating from the broad scope of the invention which shall be limited solely by the scope of the claims appended hereto.

Having thus described our invention, what we claim as new and desire to secure by Letters Patent is:

1. A structure for controlling the behavior of dislocations comprising:
a substrate of relaxed single crystal semiconductor material,
a strained epitaxial semiconductor layer formed over said substrate having a first region of an alloy of varying composition with height to provide a strain gradient up to a predetermined height therein,
said strained epitaxial semiconductor layer having a second region under strain of constant composition above said predetermined height, and
a semiconductor device formed in said second region above said first region.

2. The structure of claim 1 wherein said semiconductor device is a MOSFET.

3. The structure of claim 1 wherein said alloy is SiGe.

4. The structure of claim 1 wherein said relaxed single crystal semiconductor material is SiGe having an upper surface with a first lattice spacing.

5. The structure of claim 1 wherein said alloy composition is varied to increase strain with height in said first region of said strained epitaxial semiconductor layer.

6. The structure of claim 1 wherein said second region of constant composition is Si.

7. The structure of claim 1 wherein the strain at the lower surface of said strained epitaxial semiconductor layer is zero.

8. The structure of claim 1 wherein said substrate is strained germanium on insulator (SGOI).

9. The structure of claim 1 wherein the upper surface of said strained epitaxial semiconductor layer is roughened having a root mean square value in the range from 2 nm to 20 nm.

10. The structure of claim 1 further including one of a dielectric layer and a silicide layer on the upper surface of said strained epitaxial semiconductor layer whereby the upper end of dislocations are pinned.

11. The structure of claim 1 wherein said substrate includes a Si base and a SiGe layer graded up in Ge concentration from the lower surface to the upper surface and wherein the SiGe layer is relaxed.

12. A method for controlling the behavior of dislocations comprising:
providing a substrate of relaxed single crystal semiconductor material,
forming a strained epitaxial semiconductor layer over said substrate having a first region of an alloy of varying composition with height to provide a strain gradient up to a predetermined height therein,
said strained epitaxial semiconductor layer having a second region under strain of constant composition above said predetermined height, and
forming a semiconductor device in said second region above said first region.

13. The method of claim 12 wherein said forming a semiconductor device includes forming a MOSFET.

14. The method of claim 12 wherein said forming a strained epitaxial semiconductor layer includes forming an alloy of SiGe.

15. The method of claim 12 wherein providing a substrate of relaxed single crystal semiconductor material includes selecting said alloy of SiGe.

16. The method of claim 12 further including roughening the upper surface of said strained epitaxial semiconductor layer by one of dry etching, wet etching, epitaxial growth/etching and anodization.

17. The method of claim 16 where said roughening continues to provide a surface roughness having a root mean square value in the range from 2 nm to 20 nm.

18. The method of claim 12 further including forming one of a dielectric layer and a silicide layer on the upper surface of said strained epitaxial semiconductor layer whereby the upper end of dislocations are pinned.

19. The method of claim 18 wherein one of said dielectric layer and said silicide layer is patterned.

20. The method of claim 12 wherein said strained epitaxial semiconductor layer contains one of Ge and III-V compounds.
